(19) United States
(12) Patent Application Publication
(10) Pub. No.: US 2026/0189141 A1
(43) Pub. Date: Jul. 2, 2026

(54) MULTI-STAGE HIGH VOLTAGE CHARGE PUMP CIRCUIT WITH LOW VOLTAGE DEVICES

(71) Applicant: GlobalFoundries U.S. Inc., Malta, NY (US)

(72) Inventors: Siva Kumar Chinthu, Bangalore (IN); Palle Sundar Veerendranath, Bangalore (IN); Venkata Raju Mandapati, Banaglore (IN); Sourabh Jain, Bangalore (IN)

(21) Appl. No.: 19/007,932

(22) Filed: Jan. 2, 2025

(51) Int. Cl. H02M 3/07; G11C 11/16; G11C 13/00

(52) U.S. Cl. CPC H02M 3/073; G11C 11/1697; G11C 13/0038

(57) ABSTRACT

A charge pump structure and integrated circuit device. The charge pump structure includes a first stage charge pump unit implemented with low voltage devices that raises an input voltage using a system clock signal; and a plurality of second stage charge pump units, each implemented with low voltage devices that raise an output voltage of a prior charge pump unit using one of a series of boosted clock signals.

### BACKGROUND

The present disclosure relates to charge pumps and, more particularly, to embodiments of a multi-stage high voltage charge pump implemented with low voltage devices.

Modern integrated circuit (IC) designs often include single or multi-stage charge pumps, which are circuits configured to convert an input direct current (DC) power supply (referred to herein as a voltage input (Vin)) to at least one different DC power supply (referred to herein as a voltage output (Vout)). A single-stage charge pump can convert a Vin at a first voltage (e.g., positive supply voltage (Vdd)) to a Vout that is, for example, double the magnitude of the voltage input (i.e., Vout=2*Vin or 2*Vdd). Conventional multi-stage charge pumps generally include a number of stages in which each stage increases the voltage by a factor of one, e.g., a first stage Vin to 2*Vdd; a second stage increases 2*Vdd to 3*Vdd; a fourth stage increases 3*Vdd to 4*Vdd; and so on. Such multi-stage charge pumps are relatively complex and consume a significant amount of chip area.

### SUMMARY

Disclosed herein are embodiments of a charge pump structure. The structure can include a first stage charge pump unit implemented with first low voltage devices that raises an input voltage using a system clock signal; and a plurality of second stage charge pump units, each implemented with second low voltage devices that raise an output voltage of a prior charge pump unit using one of a series of boosted clock signals, wherein the second low voltage devices have a different voltage rating than the first low voltage devices.

Other embodiments include an integrated circuit (IC) device. The IC device includes a charge pump having: a plurality of staged charge pump units each having low voltage devices; and a plurality of boosted clock signal generators; wherein each charge pump unit increases an output voltage of a prior charge pump unit using a boosted clock signal generated from one of the plurality of boosted clock signal generators.

Two or more aspects described in this disclosure, including those described in this summary section, may be combined to form implementations not specifically described herein.

The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating an integrated circuit device having a charge pump, according to embodiments;

FIG. 2 is a schematic diagram illustrating a set of multi-stage charge pump units and a preliminary clock driver from the charge pump of FIG. 1 during a first clock phase, according to embodiments;

FIG. 3 is a schematic diagram illustrating a set of multi-stage charge pump units and a preliminary clock driver from the charge pump of FIG. 1 during a second clock phase, according to embodiments;

FIG. 4 is a schematic diagram illustrating a level shifter clock generator and stage 2 raised clock generators from the charge pump of FIG. 1, according to embodiments; and

FIG. 5 depicts an illustrative charge pump unit, according to embodiments.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

Considerations in modern integrated circuit (IC) design include, but are not limited to, performance improvement, size scaling, and power consumption. As noted, multi-stage charge pumps are relatively complex and consume a significant amount of chip area. Further, conventional high voltage multi-stage charge pumps, such as those used in eFlash memory applications, generally require 12-volt devices, which adds complexity including a separate high voltage mask during chip fabrication.

In view of the foregoing, disclosed herein are embodiments of a structure such as an (IC) integrated circuit device and, particularly, a high voltage multi-stage charge pump that can be implemented with low voltage devices, which both saves area and reduces the mask count.

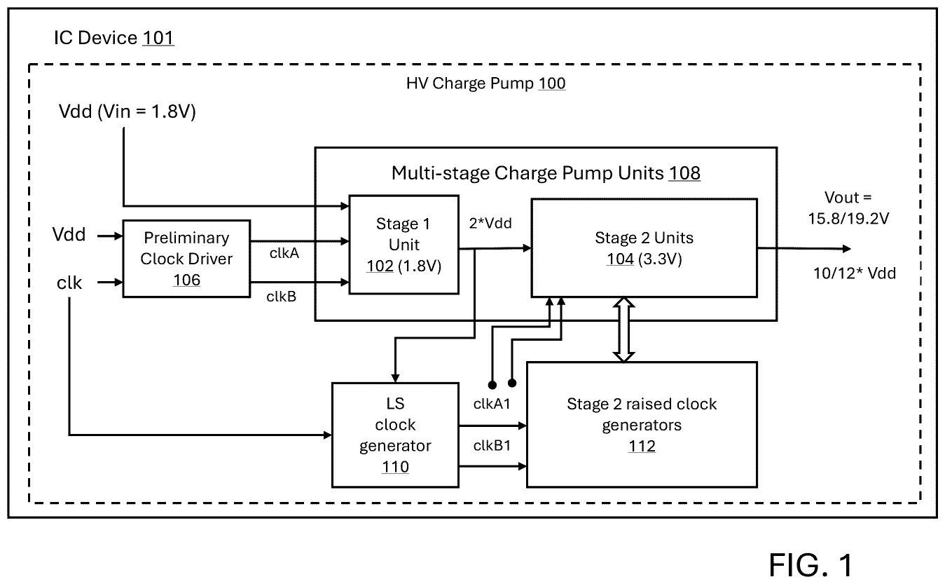

FIG. 1 depicts an IC device 101, such as an eFlash memory device, having a high voltage (HV) charge pump 100. eFlash memory is a non-volatile memory (NVM) device that, e.g., includes one-time-programmable memory (OTP), multiple-time-programmable memory (MTP), flash memory, etc., implemented using magneto-resistive RAM (MRAM) and resistive RAM (RRAM). In MRAM and RRAM devices, high voltage pulses are required to, e.g., switch the resistive state of a cell during write operations. It is understood that while HV charge pump 100 is particularly useful for eFlash memory applications, the described embodiments may be implemented in any IC device 101 or structure that requires a high voltage booster.

In the illustrative embodiment, HV charge pump 100 is configured to receive an input voltage (Vin) of 1.8V or Vdd, which is passed through a series of multi-stage charge pump units 108 and clock generators 110, 112, to increase voltage multiplication by 2*Vdd at each unit. The result for example is an output voltage of 12*Vdd or 21.6V, which can be achieved with six charge pump units. As described in further detail herein, multi-stage charge pump units 108 includes a first stage unit 102 (stage 1) having a single charge pump unit with devices that operate at 1.8V and second stage units 104 (stage 2) having, e.g., a total of five staged charge pump units, with devices that operate at 3.3V. Accordingly, while both stages use low voltage devices, the second stage low voltage devices have a different voltage rating than the first stage low voltage devices.

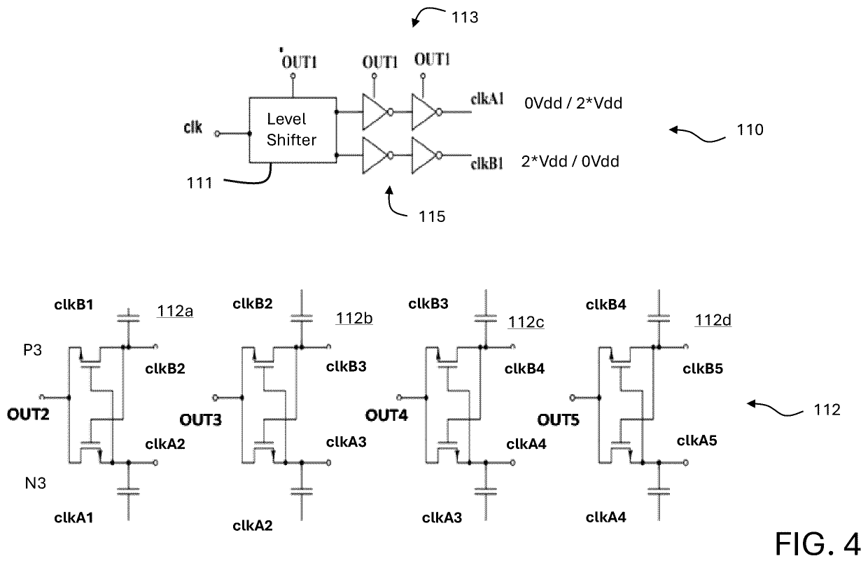

A preliminary clock driver 106 receives as input Vdd and a system clock signal (clk) and generates clkA and clkB signals that alternate between 0 and Vdd (1.8V), which are inputted to the stage 1. Stage 1 doubles the Vin voltage to a transitional voltage of 2*Vdd. A level shifter (LS) clock generator 110 utilizes the transitional voltage and the system clock signal (clk) to generate clkA1 and clkB1 that are inverted with respect to each other and that alternate between 0 and 2*Vdd (i.e., clkA1 and clkB1 each have twice the amplitude as clk). Clock signals clkA1 and clkB1 are further fed to an initial second stage charge pump unit of stage 2 and to the first of the stage 2 raised clock generators 112 (see FIG. 4). Stage 2 raised clock generators 112 each boost a previous clock signal pair by 2*Vdd.

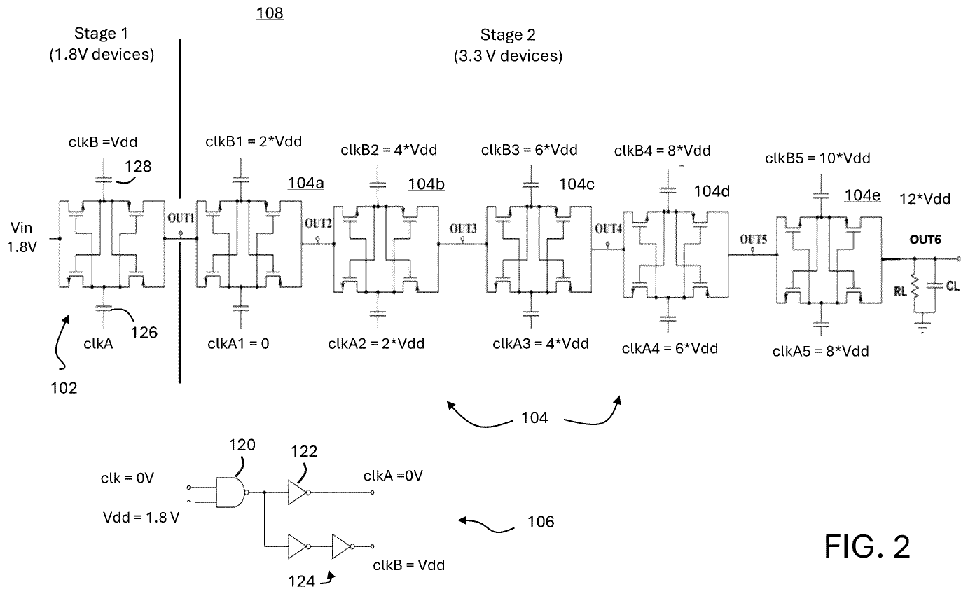

FIG. 2 depicts the first stage charge pump unit 102 and second stage charge pump units 104 in further detail, along with relevant voltage values, during a first system clock phase (clk=0). Also shown in further detail is preliminary clock driver 106 with voltage values during the first clock phase (clk=0). Preliminary clock driver 106 includes a NAND gate 120 with an output coupled to: (1) a single inverter 122 to create a first output clkA; and (2) a pair of inverters 124 to create a second output clkB. NAND gate 120 receives as input the system clock signal clk and Vdd. In this first phase where the system clock is 0 (clk=0V), clkA=0V and clkb=Vdd.

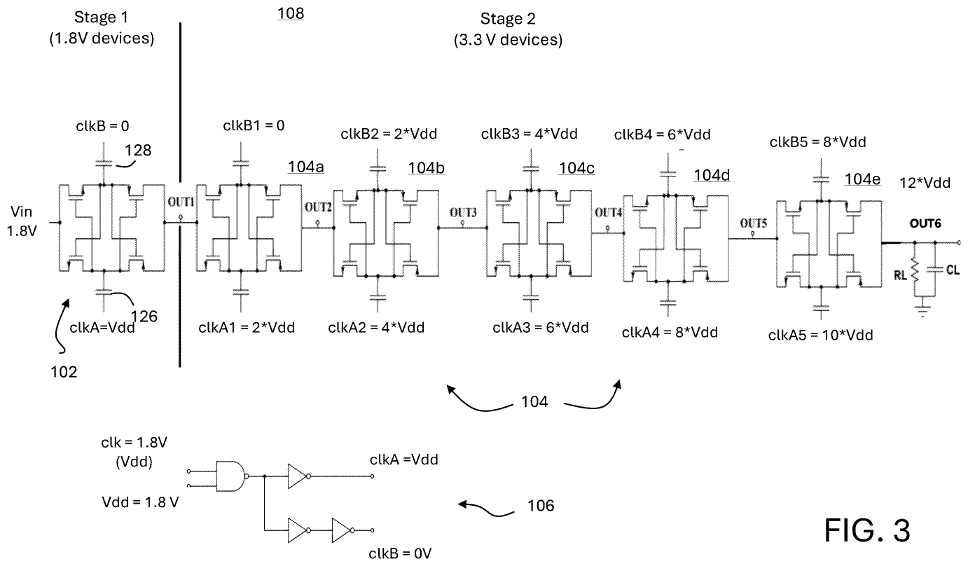

As shown, stage 1 consists of a single charge pump unit 102 (having 1.8V devices) that receives as input Vin (i.e., 1.8V) and clock signals clkA and clkB via a pair of 1.8V capacitors 126, 128. During the first clock phase shown in FIG. 2, the output of the stage 1 (OUT1) is 2*Vdd obtained from a combination of Vin and ClkB (via capacitor 128). FIG. 3 depicts the same schematic with voltage values generated during the second phase of the system clock signal (i.e., clk=Vdd), so clkA=Vdd and clkB=0V. In the second phase, the output of first stage charge pump unit 102 (OUT1) remains at 2*Vdd obtained from a combination of Vin and ClkA (via capacitor 126).

In this example, Stage 2 (having 3.3V devices) is comprised of five second stage (i.e., staged) charge pump units 104a-e. Clock signals clkA1 and clkB1, which along with OUT1 drives an initial second stage charge pump unit 104a. Signals clkA1 and clkB1 are generated by level shifter (LS) clock generator 110, an example of which is shown in detail in FIG. 4. The illustrative LS clock generator 110 includes a level shifter 111 that receives as input the system clock signal (clk) and the output of stage 1 (OUT1), and includes a set of inverters 113, 115 to generate the resulting boosted clock signals clkA1 and clkB1. A first set of inverters 113 are controlled by OUT1 so that clkA1 and clkB1 provide alternating outputs, which alternate between 0 and 2*Vdd. That is, clkA1 and clkB1 are inverted with respect to each other and have twice the amplitude of clk. During the first clock phase (FIG. 2), clkB1 is 2*Vdd and clkA1=0V. The initial second stage charge pump unit 104a receives OUT1 (2*Vdd) as input along with clkA1 and clkB1. In the first clock phase, the output of charge pump unit 104a (OUT2) is 4*Vdd, a combination of OUT1 and clkB1. In the second clock phase (FIG. 3), clkB1 is 0V and clkA1=2*Vdd. The output of charge pump unit 104a (OUT2) during the second clock phase is similarly 4*Vdd, a combination of OUT1 and clkA1.The remaining stage two charge pump units 104b-e operate similarly, except their respective clock signals are boosted by stage 2 raised clock generators 112, examples of which are shown in detail in FIG. 4, as circuits 112a-d. Subsequent pairs of clock signals generated by raised clock generators 112 have the same amplitude swing as clkA1 and clkB1 (e.g., 2*Vdd) but are each level-shifted up by 2*Vdd. For example, clkA1 and clkB1 are 0/2*Vdd, clkA2 and clkB2 are boosted to 2*Vdd/4*Vdd, clkA3 and clkB3 are boosted to 4*Vdd/6*Vdd, etc. Accordingly, clock generator 112a receives as input OUT2 (4*Vdd) from charge pump unit 104a (FIGS. 2, 3) and clkA1/clkB1, and outputs clkA2 and clkB2. During the first clock phase, clkA1=0 and clkB1=2*Vdd, so clkA2=2*Vdd and clkB2=4*Vdd, and the output of charge pump unit 104b, i.e., OUT3, is 6*Vdd. During the second clock phase, clkA1=2*Vdd and clkB1=0, so clkA2=4*Vdd and clkB2=2*Vdd, and the output of charge pump unit 104b, i.e., OUT3 is similarly 6*Vdd. Continuing with the example, clock generator 112b receives as input OUT3 (6*Vdd) from charge pump unit 104b (FIG. 2) and clkA2/clkB2, and outputs clkA3 and clkB3. During the first clock phase (FIG. 2), clkA2=2*Vdd and clkB2=4*Vdd, so clkA3=4*Vdd and clkB3=6*Vdd, and charge pump unit 102c (OUT4) is 8*Vdd. During the second clock phase (FIG. 3), clkA2=4*Vdd and clkB2=2*Vdd, so clkA3=6*Vdd and clkB3=4*Vdd, and OUT4 is similarly 8*Vdd. The same 2*Vdd increase is similarly provided by the next charge pump units 104d, 104e, i.e., OUT5=10*Vdd and OUT6=12*Vdd. In this manner, a plurality of second stage charge pump units are implemented with low voltage devices, and each raises an output voltage of a prior charge pump unit by 2*Vdd using one of a series of boosted clock signals.

In the described HV charge pump 100, Vout (i.e., OUT6), which is coupled to a load resistor (RL) and load capacitor (CL), would have a capacitance load voltage of 21.6V.

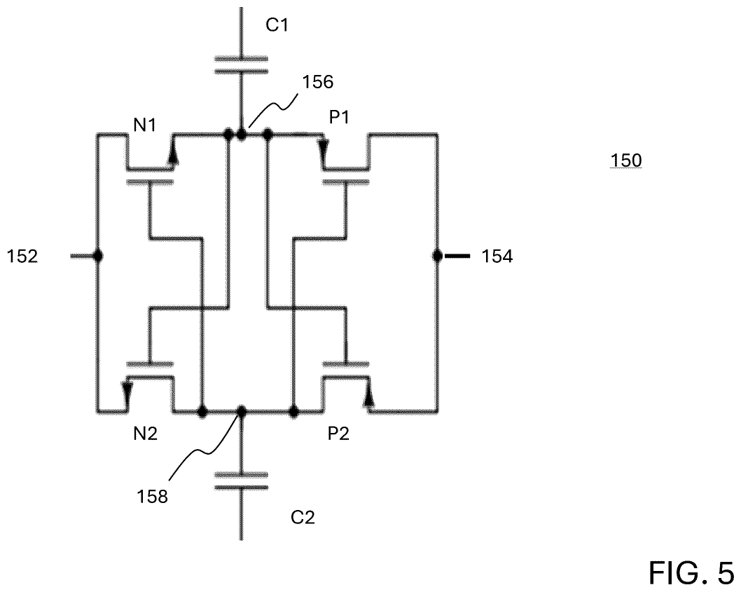

FIG. 5 depicts an example of a charge pump unit 150, which may be utilized within the HV charge pump 100. Charge pump unit 150 includes a first pair of cross coupled n-type field effect transistors (NFETs) N1, N2 connected at the input node 152, and a second pair of p-type field effect transistors (PFETs) P1, P2 connected to an output node 154. The input node 152 is connected a drain of N1 and a source of N2. The output node 154 is connected to a drain of P1 and a source of P2. The source of N1 is coupled at a first node 156 with the gates of N2 and P2 to a source of P1, and the drain of N2 is coupled to a drain of P2 with the gates of N1 and P1 at a second node 158. The first node 156 is further coupled to a capacitor C1 and the second node 158 is further coupled to a capacitor C2. In operation, the higher of the alternating clock voltage appearing at C1, C2 gets added to the voltage at input node 152 and is output at output node 154. That is, N1 and P1 turn on when the voltage at C1 is greater than the voltage at C2, and N2 and P2 turn on when the voltage at C2 is greater than the voltage at C1.

In a similar fashion, each of the stage 2 raised clock generators 112 (FIG. 4) includes a pair of cross-coupled transistors. For example, as shown in FIG. 4, generator 112a includes an input node (OUT2) coupled to a source of a PFET P3 and a drain of an NFET N3. A drain of P3 is coupled to a first capacitor and gate of N3 at a first node that outputs clkB2, and a source of N3 is coupled to a second capacitor and gate of P3 at a second node that outputs clkA2.

In the illustrative embodiments shown in FIGS. 2-5, all of the n-channel metal-oxide semiconductor (nMOS) bulk and p-channel metal-oxide semiconductor (pMOS) bulk can be connected to the source terminal. “Bulk” generally refers to the substrate material, typically a p-type semiconductor, which is connected to a separate terminal, influencing the channel formation and impacting device behavior.

The described charge pump units, level shifters and generators include a combination of both P-type transistors and N-type transistors. For purposes of illustration, the P-type transistors and N-type transistors may comprise metal oxide semiconductor field effect transistors (MOSFETs) and, particularly, P-type field effect transistors (PFETs) and N-type field effect transistors (NFETs), respectively. A MOSFET refers to a transistor with a semiconductor channel region positioned laterally between a source region and a drain region and with a gate (e.g., including a gate dielectric-gate conductor stack) adjacent to the channel region. However, it should be understood that the figures and discussion thereof are not intended to be limiting. For example, alternatively, a similar circuit structure could be formed using bipolar junction transistors (BJTs) and, particularly, PNP BJTs and NPN BJTs.

In the depicted example, all of the stage 1 devices have a first maximum voltage rating of 1.8V and the stage 2 devices have a second maximum voltage rating of 3.3V. While it is understood that stage 2 devices have a different rating than stage 1 devices, it is understood that voltage ratings other than 1.8V and 3.3V could be implemented, e.g., 0.8V and 1.5V. Further, although not shown, it should be understood that HV charge pump 100 could further include additional (or fewer) voltage shifting stages.

In the described embodiments, the required voltage level shifting can be achieved without violating the maximum voltage ratings so that device stress is avoided and operation within the safe operating area (SOA) of the transistors is maintained. Furthermore, the described circuitry can be implemented without an additional mask to fabricate high voltage (e.g., 12V) devices. Instead, the described circuitry is implemented with low voltage devices (e.g., 1.8 and 3.3V devices). Furthermore, the described circuitry can be implemented using a smaller amount of area, e.g., 250 um² as compared to 1500 um² in conventional practice.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the terminology used herein is for the purpose of describing the disclosed structures and methods and is not intended to be limiting. For example, as used herein, the singular forms “a,” “an” and “the” are intended to include the plural forms as well, unless the context clearly indicates otherwise. Additionally, as used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A charge pump structure, comprising:
a first stage charge pump unit implemented with first stage low voltage devices that raises an input voltage using a system clock signal; and
a plurality of second stage charge pump units, each implemented with second stage low voltage devices that raise an output voltage of a prior charge pump unit using one of a series of boosted clock signals, wherein the second stage low voltage devices have a different voltage rating than the first stage low voltage devices.

2. The charge pump structure of claim 1, wherein the first stage low voltage devices have a maximum voltage rating lower than the second stage low voltage devices.

3. The charge pump structure of claim 2, wherein the maximum voltage rating of the first stage low voltage devices is 1.8V and the maximum voltage rating of the second stage low voltage devices is 3.3V.

4. The charge pump structure of claim 1, having a total of five second stage charge pump units.

5. The charge pump structure of claim 1, further comprising a preliminary clock driver that generates alternating clock signals from the system clock signal.

6. The charge pump structure of claim 1, further comprising a plurality of raised clock generators that generate the series of boosted clock signals, wherein each boosted clock signal is generated using a previously generated boosted clock signal, and each boosted clock signal is greater than the previously generated boosted clock signal.

7. The charge pump structure of claim 1, further comprising a level shifter clock generator that generates an amplified clock signal for an initial second stage charge pump unit, the initial second stage charge pump unit configured to boost an output voltage from the first stage charge pump unit.

8. The charge pump structure of claim 1, wherein the first stage charge pump unit raises an input voltage from Vdd to 2*Vdd.

9. The charge pump structure of claim 8, wherein the second stage charge pump units each increase the output voltage of the prior charge pump unit by 2*Vdd.

10. The charge pump structure of claim 1, wherein the charge pump structure is embodied in one of a magneto-resistive random-access memory (MRAM) or a resistive random-access memory (RRAM).

11. An integrated circuit (IC) device, comprising:
a charge pump that includes:
a plurality of staged charge pump units each having low voltage devices; and
a plurality of boosted clock signal generators;
wherein each charge pump unit increases an output voltage of a prior charge pump unit using a boosted clock signal generated from one of the plurality of boosted clock signal generators.

12. The IC device of claim 11, wherein the charge pump further includes a first stage charge pump unit having low voltage devices that raises an input voltage using a system clock signal and outputs a raised voltage to the plurality of staged charge pump units.

13. The IC device of claim 12, further comprising a preliminary clock driver that generates alternating clock signals from the system clock signal.

14. The IC device of claim 13, wherein the low voltage devices in the first stage charge pump unit have a maximum voltage rating lower than the low voltage devices in the staged charge pump units.

15. The IC device of claim 14, wherein the maximum voltage rating of the low voltage devices in the first stage charge pump unit is 1.8V and the maximum voltage rating of the low voltage devices in the charge pump units is 3.3V.

16. The IC device of claim 15, wherein the charge pump includes a total of six charge pump units.

17. The IC device of claim 11, wherein the plurality of raised clock generators generates a series of boosted clock signals, wherein each boosted clock signal is generated using a previously generated boosted clock signal, and each boosted clock signal is greater than the previously generated boosted clock signal.

18. The IC device of claim 11, further comprising a level shifter clock generator that generates an amplified clock signal for the first of the staged charge pump units.

19. The IC device of claim 12, wherein the first stage charge pump unit raises an input voltage from Vdd to 2*Vdd, and the plurality of staged charge pump units each increase the output voltage of the prior charge pump unit by 2*Vdd.

20. The IC device of claim 11, wherein the IC device comprises one of a magneto-resistive random-access memory (MRAM) or a resistive random-access memory (RRAM).
